(19) United States
(12) Patent Application Publication
(10) Pub. No.: US 2014/0356060 A1
(43) Pub. Date: Dec. 4, 2014

(54) FASTENING DEVICE FOR BACKPLANE

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventors: XIAO-GANG YIN, Shenzhen (CN); JUN-HUI WANG, Shenzhen (CN)

(73) Assignees: HONG FU JIN PRECISION INDUSTRY (ShenZhen) CO., LTD., Shenzhen (CN); HON HAI PRECISION INDUSTRY CO., LTD., New Taipei (TW)

(21) Appl. No.: 14/056,969

(22) Filed: Oct. 18, 2013

(30) Foreign Application Priority Data
Jun. 3, 2013 (CN) 2013102145829

(51) Int. Cl. H05K 5/02

(52) U.S. Cl. CPC H05K 5/0221
USPC 403/322.1

(57) ABSTRACT

A fastening device for fastening a backplane includes an enclosure, a fastening member, and a pivoting member. The enclosure includes a bottom plate, a top plate opposite to the bottom plate, and a number of partition plates connected to the bottom plate and the top plate. The bottom plate forms a stop element. The stop element and the partition plates sandwiches the backplane. The fastening member is fastened to a top side of the backplane, and is supported on the top plate. The pivoting member is pivotably connected to the top plate. The pivoting member is operable to rotate to sandwich the fastening member with the top plate.

### BACKGROUND

1. Technical Field

The present disclosure relates to a fastening device for fastening a backplane in place.

2. Description of Related Art

A backplane is configured in a server. Hard disk drives are communicated with a motherboard through the backplane. The backplane is generally fastened to an enclosure of the server by screws. Accordingly, a screwdriver is needed in fastening the backplane in the enclosure. However, the operation of the screwdriver in the relatively small space of the enclosure is inconvenient.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of a fastening device together with a backplane, wherein the fastening device includes two fastening members and two pivoting members.

FIG. 2 is an enlarged view of a circled portion II of FIG. 1.

FIG. 3 is an enlarged view of one of the fastening members of FIG. 1.

FIG. 4 is an enlarged view of one of the pivoting members of FIG. 1.

FIG. 5 is an assembled, isometric view of FIG. 1.

FIG. 6 is a partial view of FIG. 5, and viewed from another perspective.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean “at least one.”

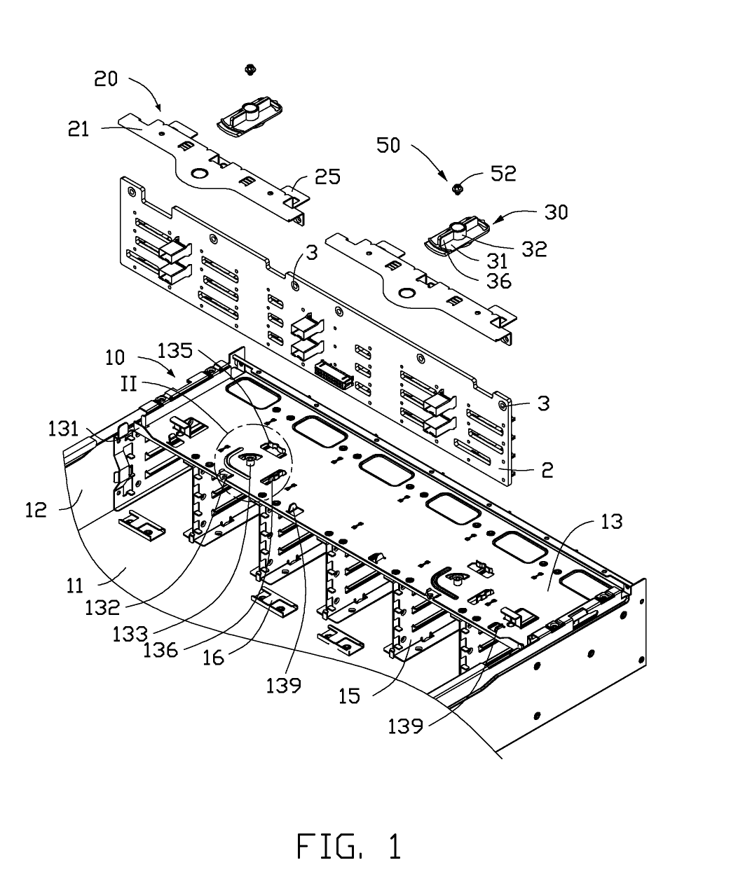

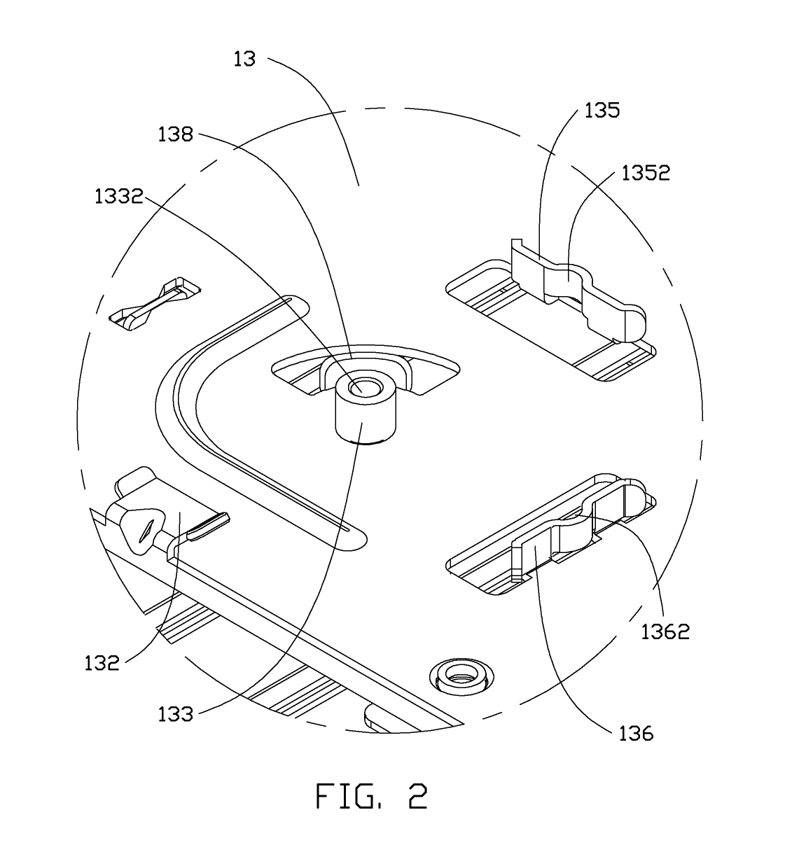

FIGS. 1 and 2 show an exemplary embodiment of a fastening device for fastening a backplane 2. Three through holes 3 are defined in a top side of the backplane 2, near each of opposite ends of the backplane 2. The fastening device includes an enclosure 10, two fastening members 20, and two pivoting members 30.

The enclosure 10 includes a bottom plate 11, two side plates 12 extending up from opposite sides of the bottom plate 11, a top plate 13 connected between tops of the side plates 12, and a plurality of partition plates 15 connected between the top plate 13 and the bottom plate 11. A plurality of stop elements 16 is formed on the bottom plate 11, located in front of the partition plates 15. A flange 131 perpendicularly extends up from a front side of the top plate 13. Two stop tabs 132 extend backward from a top side of the flange 131. Four extension tabs 139 extend up from the top plate 13, near the flange 131. Two protrusions 133 extend up from the top plate 13. Each protrusion 133 axially defines a locking hole 1332. Two first bars 135 extend up from the top plate 13, located behind the protrusions 133 respectively. Each first bar 135 defines a positioning slot 1352 facing the corresponding protrusion 133. Two second bars 136 extend up from the top plate 13, near the protrusions 133 respectively. The second bars 136 are perpendicular to the corresponding first bars 135. Each second bar 136 defines a positioning slot 1362 facing the corresponding protrusion 133. Two arc-shaped limitation tabs 138 extend up from the top plate 13. The limitation tabs 138 surround the protrusions 133.

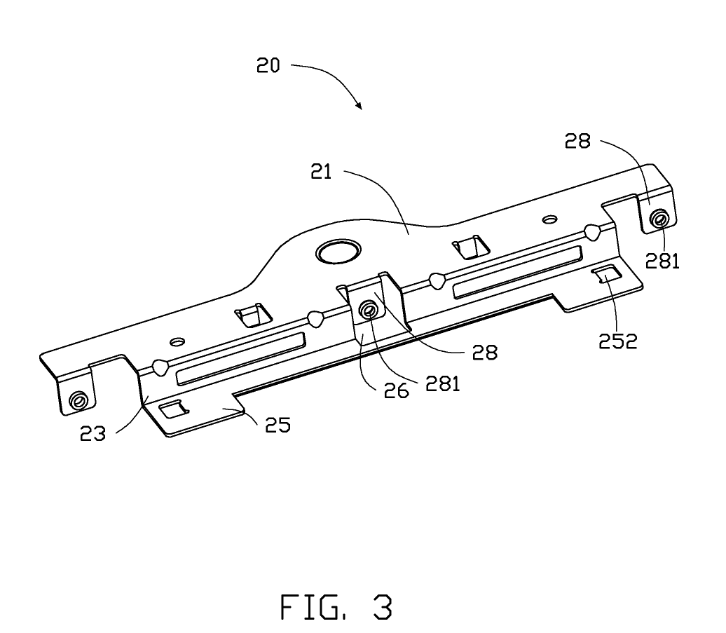

FIG. 3 shows each fastening member 20 including a top wall 21, a sidewall 23 extending down from a side of the top wall 21, and a bottom wall 25 extending from a bottom of the sidewall 23 in a direction far away from the top wall 21. An opening 26 is defined in a middle of the fastening member 20, extending through the top wall 21 and the sidewall 23. Three fastening tabs 28 extend down from the top wall 21. Two of the fastening tabs 28 are located at opposite ends of the top wall 21, the other fastening tab 28 is located at a top edge of the opening 26. Each fastening tab 28 defines a fastening hole 281. Two through holes 252 are defined in opposite ends of the bottom wall 25.

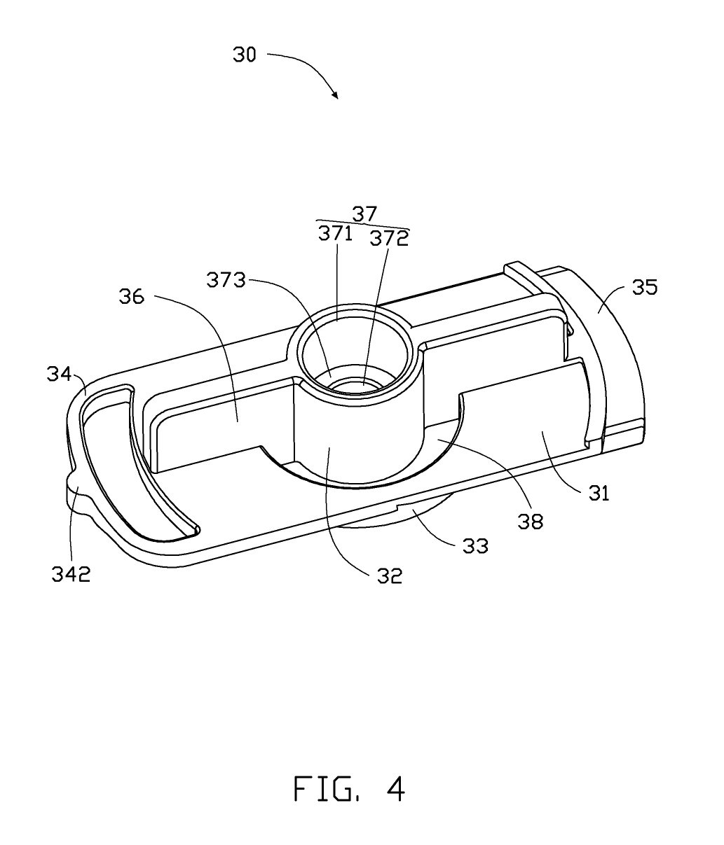

FIG. 4 shows each pivoting member 30 including a base body 31, a pole 32 extending up from a middle of the base body 31, and a supporting foot 33 extending down from the middle of the base body 31. Two operation portions 36 extending from the pole 32 toward a first end 34 and a second end 35 respectively, for operating the pivoting member 30 conveniently. A bump 342 is formed on the first end 34 of the base body 31.

The pole 32 axially defines a pivoting hole 37 extending through the supporting foot 33. The pivoting hole 37 includes a first hoe 371 and a second hole 372 communicating with a bottom of the first hole 371. The diameter of the first hole 371 is greater than the diameter of the second hole 372. An arc-shaped mounting hole 38 is defined in the base body 31, surrounding the pole 32 and located at same sides of the operation portions 36.

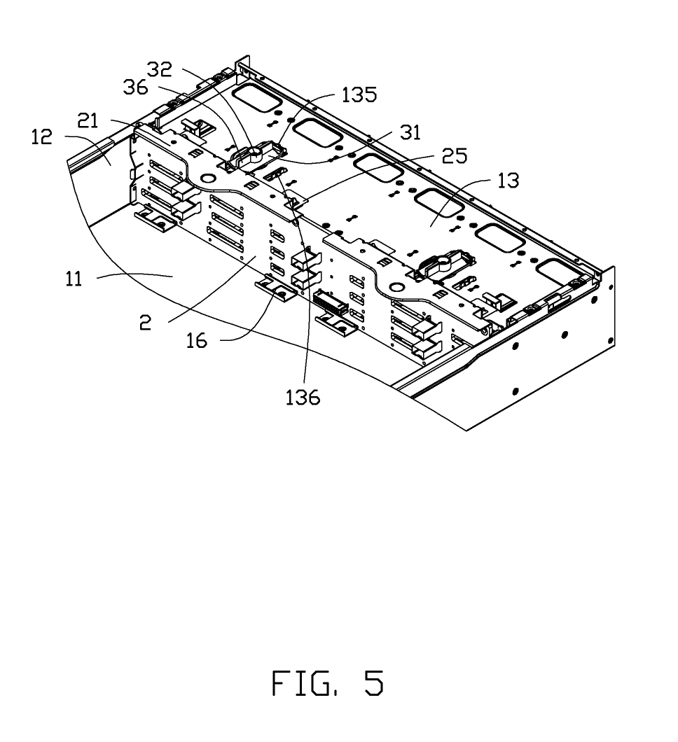

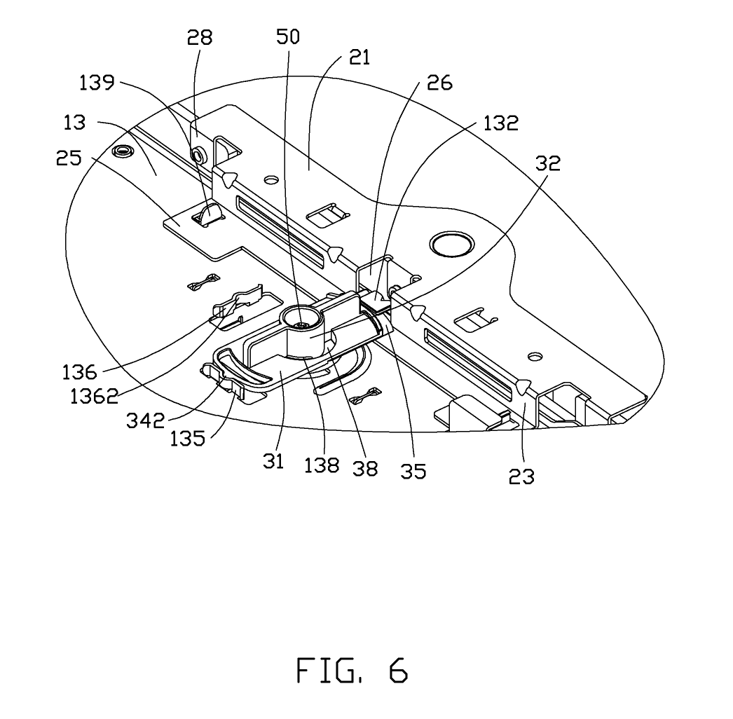

FIGS. 5 and 6 show in assembly, the protrusions 133 engage in the second holes 372 of the pivoting members 30, to pivotably connect the pivoting members 30 to the protrusions 133. The limitation tabs 138 extend through the mounting holes 38. Two fasteners 50, such as screws, extend through the first holes 371 and engage in the locking holes 1332. Heads 52 of the fasteners 50 abut against bottom surfaces 373 of the first holes 371, to prevent the pivoting members 30 from moving up. When the backplane 2 has not been mounted to the enclosure 10, the pivoting members 30 can be rotated to allow the bumps 342 to engage in the positioning slots 1362 of the second bars 136.

To mount the backplane 2, three screws extend through three through holes 3 near an end of the backplane 2, and engage in the fastening holes 281 of one of the fastening members 20; three screws extend through the other three through holes 3, and engage in the fastening holes 281 of the other fastening member 20, to fasten the fastening members 20 to the top side of the backplane 2. The backplane 2 is supported on the bottom plate 11, and is sandwiched between the partition plates 15 and the stop elements 16. The bottom walls 25 of the fastening members 20 are supported on the top plate 13. The stop tabs 132 extend through the openings 26. The extension tabs 139 extend through the through holes 252. The pivoting members 30 are rotated, to allow the bumps 342 to engage in the positioning slots 1352 of the first bars 135. The second ends 35 of the pivoting members 30 block top surfaces of the bottom walls 25. The stop tabs 132 are located above the second ends 35 of the pivoting members 30, to block the second ends 35 of the pivoting members 30. Therefore, the backplane 2 is fastened to the enclosure 10.

The top plate 13 of the enclosure 10 includes two limitation tabs 138 to extend through the mounting holes 38 of the pivoting members 30. The limitation tabs 138 can limit the range of rotation of the pivoting members 30, to prevent the first ends 34 of the pivoting members 30 from rotating to the bottom walls 25, and prevent the second ends 35 of the pivoting members 30 from rotating toward the first bars 135.

After the fastening members 20 of the fastening device are fastened to the top side of the backplane 2, the backplane 2 is placed into the enclosure 10. The operator just rotates the pivoting members 30, the backplane 2 is then fastened in place, which is convenient.

Even though numerous characteristics and advantages of the embodiments have been set forth in the foregoing description, together with details of the structure and the functions of the embodiments, the disclosure is illustrative only, and changes may be made in details, especially in the matters of shape, size, and arrangement of parts within the principles of the embodiments to the full extent indicated by the broad general meaning of the terms in which the appended claims are expressed.

What is claimed is:

1. A fastening device for fastening a backplane, comprising:
an enclosure comprising a bottom plate, a top plate opposite to the bottom plate, and a plurality of partition plates connected between the bottom plate and the top plate, the bottom plate forming a stop element, the stop element and the plurality of partition plates being configured for sandwiching the backplane;
a fastening member to be fastened to a top side of the backplane, and supported on the top plate; and
a pivoting member pivotably connected to the top plate, the pivoting member operable to rotate to sandwich the fastening member with the top plate.

2. The fastening device of claim 1, wherein the pivoting member defines a pivoting hole, a protrusion extends from the top plate and pivotably engages in the pivoting hole.

3. The fastening device of claim 2, wherein the protrusion axially defines a locking hole, the pivoting hole includes a first hole and a second hole communicating with a bottom of the first wall, a fastener engages in the locking hole and abuts against a bottom surface of the first hole.

4. The fastening device of claim 2, wherein the pivoting member includes a base body, a pole extending up from the base body, and a supporting foot extending down from the base body to be supported on the top plate, the pivoting hole is axially defined in the pole.

5. The fastening device of claim 4, wherein the top plate forms a first bar opposite to the fastening member, the first bar defines a first positioning slot facing the pivoting member, a bump extends from a first end of the base body, the pivoting member is operable to rotate to allow the bump to engage in the first positioning slot.

6. The fastening device of claim 5, wherein the top plate forms a second bar perpendicular to the first bar, the second bar defines a second positioning slot facing the pivoting member, the pivoting member is operable to rotate to allow the bump to engage in the second positioning slot.

7. The fastening device of claim 4, wherein two operation portion extend form opposite sides of the pole, the base body defines an arc-shaped mounting hole surrounding the pole, the mounting hole is located at same sides of the operation portions, an arc-shaped limitation tab extends from the top plate and extends through the mounting hole.

8. The fastening device of claim 1, wherein the fastening member comprises a top wall fastened to the top side of the backplane, a sidewall extending down from the top wall, and a bottom wall extending from a bottom of the sidewall and supported on the top plate.

9. The fastening device of claim 8, wherein the bottom wall extends from the sidewall along a direction far away from the top wall.

10. The fastening device of claim 8, wherein the fastening member defines an opening extending through the top wall and the sidewall, a flange extends up from a front side of the top plate, a stop tab extends from the flange and extends through the opening, the stop tab is located above the pivoting member to block the pivoting member.

11. The fastening device of claim 8, wherein two through holes are defined in opposite ends of the bottom wall, the top plate forms two extension tabs extending through the through holes.
